(19) United States
(12) Patent Application Publication
(10) Pub. No.: US 2020/0349857 A1
(43) Pub. Date: Nov. 5, 2020

(54) VIRTUAL REALITY PC CASE / SIMULATION CHASSIS

(71) Applicant: Sean Rojas, Carmichael, CA (US)

(72) Inventor: Sean Rojas, Carmichael, CA (US)

(21) Appl. No.: 16/865,808

(22) Filed: May 4, 2020

Related U.S. Application Data
(60) Provisional application No. 62/841,890, filed on May 2, 2019.

(51) Int. Cl. G09B 9/02; G06F 3/01; G06F 3/16; G06F 1/20; H05K 7/20

(52) U.S. Cl. CPC G09B 9/02; G06F 3/011; G06F 3/16; G09B 9/05; H05K 7/2039; H05K 7/20172; G06F 1/20

(57) ABSTRACT

A virtual reality simulator is disclosed comprising a chassis configured to receive a cockpit. The cockpit is comprised of one or more control elements to operatively control a virtual reality simulation. A computing device receives input from the one or more control elements and provides a plurality of output signals to a motion system engaged with the chassis. The computing device is positioned within a foldable housing to operate as a heat sink.

### CROSS-REFERENCE TO RELATED APPLICATIONS

The present application claims priority to U.S. Provisional Patent Application 62/841,890 filed on May 2, 2019, entitled “VIRTUAL REALITY SIMULATION CHASIS” the entire disclosure of which is incorporated by reference herein.

### TECHNICAL FIELD

The embodiments generally relate to virtual reality simulators and more specifically relate to modular simulation chassis.

### BACKGROUND

The advent of computer systems has since lead to the possibility for virtual reality simulators. Vehicle simulators have been used for various purposes, including research, training, vehicle engineering, and entertainment. As computing systems continue to progress, the ability to simulate real-life scenarios is increasing.

Simulators have become increasingly prevalent and useful for reproducing the operational experience of motor vehicles, aircraft, trains, spacecraft, and boats as many companies have adopted virtual reality scenarios when conducting training exercises. Such systems may also be used for entertainment by individuals as materials have become more accessible.

Many simulators are built for a specific vehicle, causing the production cost to remain prohibitively high for many small companies and individuals. In the current arts, a vehicle-specific chassis is attached to a motion system controlled by a computer. The vehicle-specific chassis may not provide the ability to select various control elements, vehicle types, or virtual-reality simulation systems currently on the market.

### SUMMARY OF THE INVENTION

This summary is provided to introduce a variety of concepts in a simplified form that is further disclosed in the detailed description of the embodiments. This summary is not intended to identify key or essential inventive concepts of the claimed subject matter, nor is it intended for determining the scope of the claimed subject matter.

The embodiments provided herein disclose a virtual reality simulator comprising a chassis configured to receive a cockpit. The cockpit is comprised of one or more control elements to operatively control a virtual reality simulation. A computing device receives input from the one or more control elements and provides a plurality of output signals to a motion system engaged with the chassis. The computing device is positioned within a housing having a foldable footwell to releasably engage with at least one of the control elements.

The embodiments may be utilized to simulate a real-world vehicle, such as unmanned aircraft to provide a virtual reality operating environment. For example, the user may engage with the virtual reality simulation system to pilot a drone aircraft at a remote location. In such, the virtual reality simulation system provides a plurality of output signals to a remote vehicle at a remote location in reference to the virtual reality simulation chassis. Similarly, the system may be used to simulate real-world operating characteristics of a vehicle.

In one aspect, the virtual reality simulator is provided with an interchangeable cockpit which may simulate various vehicle types including a motor vehicle, an aircraft, a spacecraft, a boat, a train, or a motorcycle, among other vehicle types known in the arts.

In one aspect, the cockpit releasably engages with a plurality of control elements which may include a steering wheel, one or more pedals, one or more shifters, and one or more joysticks.

In one aspect, a plurality of virtual reality simulators may be used in series to permit multiple users to engage in a simulation experience.

In one aspect, the computing system is in operable communication with a display to provide a visual stimulus to a user.

In one aspect, an audio system is provided to provide sensory stimulus to the user.

In one aspect, the foldable housing is comprised of one or more fans to actively cool the housing.

### BRIEF DESCRIPTION OF THE DRAWINGS

A complete understanding of the present embodiments and the advantages and features thereof will be more readily understood by reference to the following detailed description when considered in conjunction with the accompanying drawings wherein:

FIG. 1 illustrates a perspective view of the virtual reality simulation chassis, according to some embodiments;

FIG. 2 illustrates a perspective view of the virtual reality simulation chassis and foldable housing, according to some embodiments;

FIG. 3 illustrates a perspective view of the rear side of the foldable housing, according to some embodiments;

FIG. 4 illustrates a perspective view of the rear side of the foldable housing with the foldable housing in an unfolded configuration, according to some embodiments;

FIG. 5 illustrates a perspective view of the rear side of the foldable housing with the foldable housing in a folded configuration, according to some embodiments;

FIG. 6 illustrates a block diagram of the virtual reality simulation system, according to some embodiments;

FIG. 7 illustrates a perspective view of the housing and electrical components; according to some embodiments;

FIG. 8 illustrates a perspective view of the housing and foldable footwell, according to some embodiments; and

FIG. 9 illustrates a perspective view of the virtual reality simulation chassis cockpit, according to some embodiments.

### DETAILED DESCRIPTION

The specific details of the single embodiment or variety of embodiments described herein are to the described system and methods of use. Any specific details of the embodiments are used for demonstration purposes only, and no unnecessary limitations or inferences are to be understood therefrom.

Before describing in detail exemplary embodiments, it is noted that the embodiments reside primarily in combinations of components and procedures related to the system and methods of use. Accordingly, the system components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

In general, the embodiments presented herein relate to a virtual reality simulator chassis and virtual reality simulation system which utilizes the chassis to provide a virtual or augmented reality experience to one or more users. The virtual reality simulation system allows for a user or a plurality of users to engage in a variety of vehicle simulations, which may be performed in tandem. The simulator chassis may receive a variety of cockpit components and control elements to simulate various vehicles known in the arts.

As used herein, the term “vehicle” may be used to the described motor or engine driven vehicles, trains, aircraft, boats, motorcycles, spacecraft, or as a simulator to direct unmanned aerial vehicles from a remote location. One skilled in the arts will readily understand that a variety of vehicle types and configurations may be simulated using the virtual reality simulation chassis. Further, the vehicle may correspond to a real-world vehicle or may be configured as an imaginary vehicle which does not exist in the real-world.

In general, the embodiments provided herein relate to a virtual reality simulator configured to imitate the cockpit of a vehicle such that the user experiences a realistic interaction with the simulated vehicle and its components. For example, the virtual reality simulation chassis resembles a real-world vehicle, to provide the user with a realistic experience of operating the vehicle. The cockpit may include various control elements commonly found in vehicles including operating control interfaces, joysticks, gear selectors, steering wheels and the like, displays, accelerators, brakes, HVAC systems, audio systems, status displays, emergency indicators, vehicles status indicators, and similar elements known in the arts. The system may be used for training purposes to provide a realistic operating experience or for recreation to provide a fun operating experience to the user.

The embodiments provided herein may be utilized to simulate a real-world vehicle, such as unmanned aircraft to provide a virtual reality operating environment. For example, the user may engage with the virtual reality simulation system to pilot a drone aircraft at a remote location. In such, the virtual reality simulation system provides a plurality of output signals to a remote vehicle at a remote location in reference to the virtual reality simulation chassis.

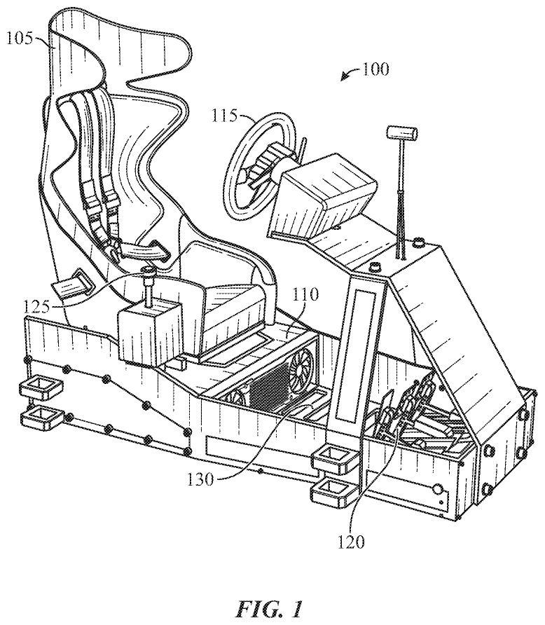

FIG. 1 illustrates the virtual reality simulation chassis 100 according to an exemplary embodiment. The chassis 100 releasably engages with a plurality of cockpit components, for example, a seat 105. The seat 105 releasably engages to a housing 110 positioned under the seat 105. Various control elements are releasably engaged to the chassis 100 and/or the cockpit components such as a steering wheel 115, pedals 120, and a shifter 125. Control elements may also include, for example, a joystick for an aircraft or spacecraft vehicle simulator. In the illustrated example, the pedals 120 are mounted to a foldable footwell 130.

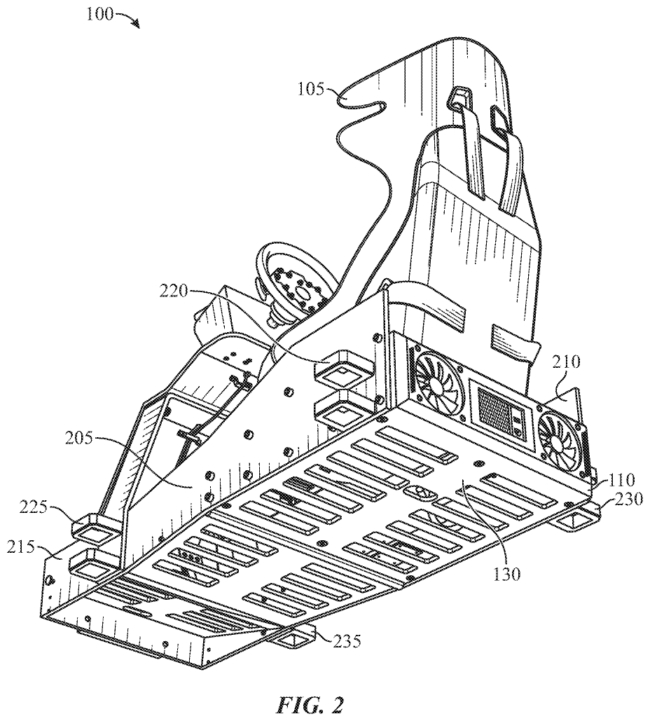

FIG. 2 illustrates a perspective view of the bottom of the chassis 100 having a first side 205, a second side 210, and a front member 215 each connected to a foldable footwell 130. The housing 110 is retained between the footwell 130 and the seat 105. Sets of receivers 220,225,230,235 attach to a motion system to provide realistic motion simulation during a virtual simulation. The motion system may allow for pitch, roll, and yaw of the chassis during a simulated experience in response to user input to the various control elements or events occurring in the simulation experience.

The cockpit is designed advantageously for one or more users, each also referred to as a player or passenger. The virtual reality simulation system is a simulation environment designed for one or multiple users with each user positioned in their own cockpit, or a shared cockpit. The interactive computer system includes, but is not limited to, the computer, interactive program and related software, any network necessary to tie multiple users (if present) together. Multiples of the cockpit are typically then located at a particular site but may also be located at remote sites.

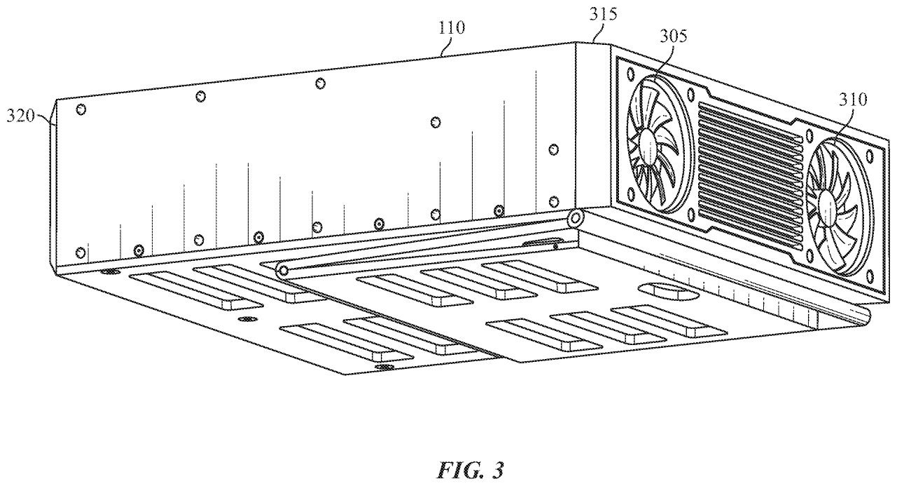

FIG. 3 illustrates the housing 110 which is dimensioned to retain a computing device and various associated components to operate the virtual reality simulation. Cooling elements, such as fans 305,310, are positioned at a first end 315 and a second end 320 of the housing to actively cool the computing device components during operation. Additional heat-conducting components may be positioned within the housing or as a part of the housing to operate as a heat sink. Various components of the computing device may be mounted using vibration reducing mounts, such as neoprene rubber isolation mounts, to reduce vibration during operation.

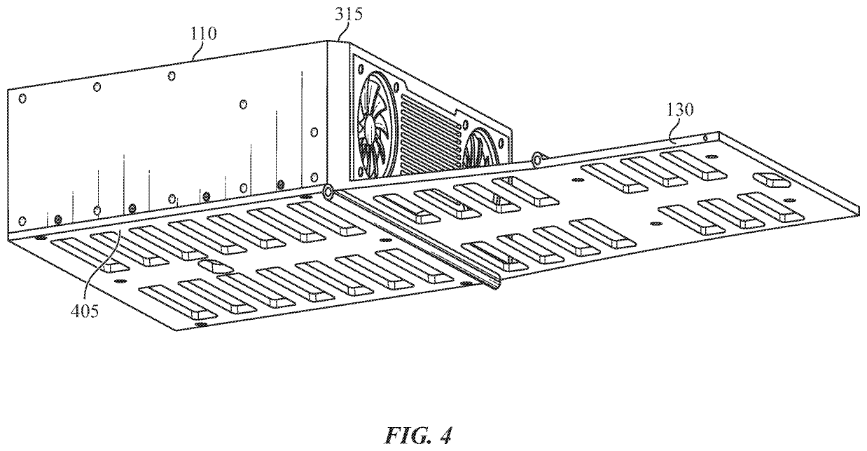

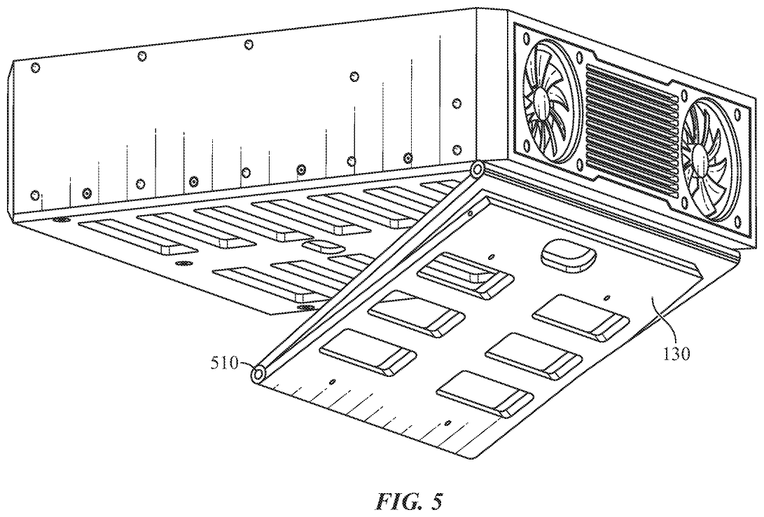

FIG. 4 illustrates the footwell 130 in an unfolded configuration. The footwell 130 is attached to the bottom side 405 of the first end 315 of the housing 110. The footwell 130 is illustrated folding in a half-fold. One skilled in the arts will understand that the footwell 130 may fold in various configurations such as a tri-fold, z-fold, or multi-panel accordion fold. Similarly, FIG. 5 illustrates the footwell 130 in a folded configuration. The footwell 130 may fold using hinges 510, or similar devices known in the arts.

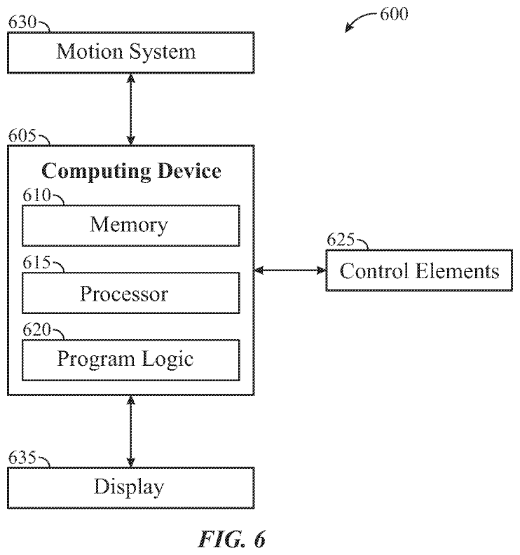

FIG. 6 illustrates a block diagram of the virtual reality simulation system 600. A computing device 605 is comprised of a memory 610 and a processor 615 to execute instructions related to program logic 620 for various virtual reality simulation systems. The one or more control elements 625 transmit an output signal to the computing device 605 which transmits an output signal to the motion system 630 configured to affect the chassis during a simulation. A display 635, which may include both audio and visual components, provides a virtual reality simulation via audio and visual stimulus to the user. The user may then react to the audio and visual stimulus using the control elements 625 throughout the simulation.

In some embodiments, the audio system is in operable communication with the virtual reality simulation system 600 to provide sound in correlation to actions provided by the user or sound in correlation with the simulated environment.

The display 635 may include a virtual reality headset similar to headsets known in the arts, which may be in operable communication with the virtual reality simulation system 600 to provide a complimentary visual and auditory experience to the user.

Processors 615 suitable for the execution of a computer program include both general and special purpose microprocessors and any one or more processors of any digital computing device. The processor 615 will receive instructions and data from a read-only memory or a random-access memory or both. The essential elements of a computing device 605 are a processor 615 for performing actions in accordance with instructions and one or more memory 610 devices for storing instructions and data. Generally, a computing device 605 will also include, or be operatively coupled to receive data from or transfer data to, or both, one or more mass storage devices for storing data, e.g., magnetic, magneto-optical disks, or optical disks; however, a computing device need not have such devices. Moreover, a computing device 605 can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive).

A network interface may be configured to allow data to be exchanged between the virtual reality simulation system 600 and other devices attached to a network, such as other computer systems, or between nodes of the virtual reality simulation system 600. In various embodiments, the network interface may support communication via wired or wireless general data networks, such as any suitable type of Ethernet network, for example, via telecommunications/telephony networks such as analog voice networks or digital fiber communications networks, via storage area networks such as Fiber Channel SANs, or via any other suitable type of network and/or protocol.

The memory 610 may include application instructions, configured to implement certain embodiments, and a database, comprising various data accessible by the application instructions. The application instructions may include software elements corresponding to one or more of the various embodiments described herein. For example, application instructions may be implemented in various embodiments using any desired programming language, scripting language, or combination of programming languages and/or scripting languages (e.g., C, C++, C#, JAVA®, JAVASCRIPT®, PERL®, etc.). Application instructions may include virtual reality systems configured to provide a virtual driving, piloting, or likewise experience to the user such that the virtual reality system is used in tandem with the virtual reality simulation chassis described in the various embodiments provided herein.

The memory 610 may be used to store operation characteristics of one or more vehicles, such that the user may select a vehicle to simulate. The memory 610 may then provide operating instructions to the processor 615 to output operating characteristics which correspond to the vehicle's real-world operating characteristics. In one example, the user may select to simulate an automatic transmission sports car which has increased acceleration and speed and nimble handling characteristics. In contrast, the user may select to simulate a freight truck which having slower acceleration and a manual transmission, requiring the user to utilize control elements to shift gears while operating the simulator.

The steps and actions of the virtual reality simulation system 600 described in connection with the embodiments disclosed herein may be embodied directly in hardware, in a software module executed by a processor 615, or in a combination of the two. A software module may reside in RAM, flash memory, ROM memory, EPROM memory, EEPROM memory, registers, a hard disk, a removable disk, a CD-ROM, or any other form of storage medium known in the art. An exemplary storage medium may be coupled to the processor 615 such that the processor 615 can read information from, and write information to, the storage medium. In the alternative, the storage medium may be integrated into the processor 615. Further, in some embodiments, the processor 615 and the storage medium may reside in an Application Specific Integrated Circuit (ASIC). In the alternative, the processor and the storage medium may reside as discrete components in a computing device. Additionally, in some embodiments, the events or actions of a method or algorithm may reside as one or any combination or set of codes and instructions on a machine-readable medium or computer-readable medium, which may be incorporated into a computer program product.

FIG. 7 illustrates the interior cavity of the housing 110 having a plurality of components mounted to at least one interior surface 702. Each component may be retained in position via a plurality of mounting components. The mounting components may be a bracket, clip, mounting arm, or similar mounting component known in the arts. The mounting components retain computing components, electrical components, and the like within the interior cavity of the housing 110 during operation of the virtual reality simulator chassis. In the illustrated embodiment, first, second, and GPU brackets 704, 706, 708 are mounted to the interior surface 702 to retain the GPU 710 in position within the interior cavity of the housing 110. A solid-state drive (SSD) mounting bracket 712 retain the SSD 714 to the interior surface 702, while the power supply unit (PSU) mounting bracket 716 retains the PSU 718 to the interior surface 702.

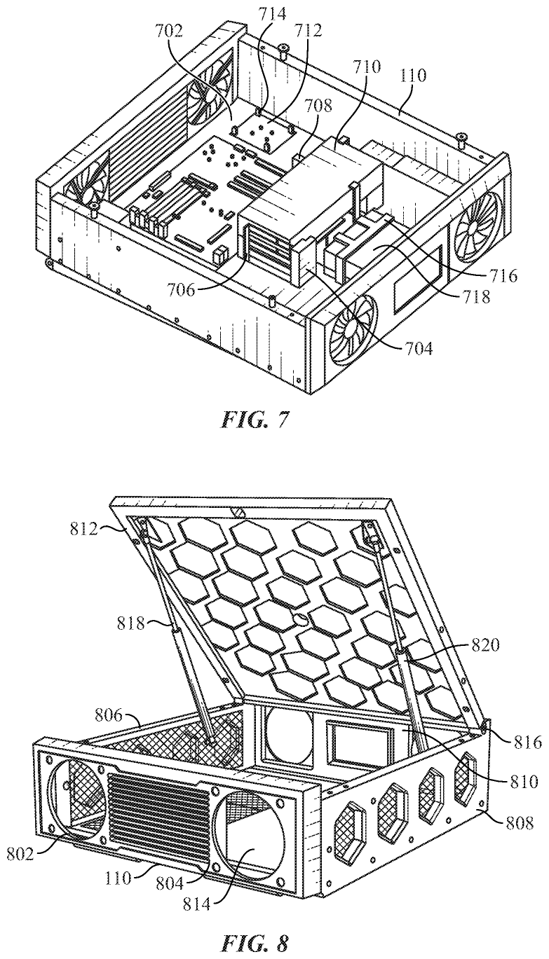

FIG. 8 illustrates the housing 110 comprising a plurality of apertures, including aperture 802 to mount a fan to cool the internal components contained within the housing as described hereinabove. Apertures may be positioned on any combination of the first, second, third and fourth sidewalls 804, 806, 808, 810. Similarly, one or more apertures may be positioned on the top panel 812 and bottom panel 814. The top panel 812 may be pivotally engaged with the housing 110 via one or more hinges 816 to allow for the top panel 812 to be opened and closed to access the interior cavity of the housing 110. Actuators 818, 820 may be provided to facilitate raising and lowering the top panel 812 and bias the opened position and closed position.

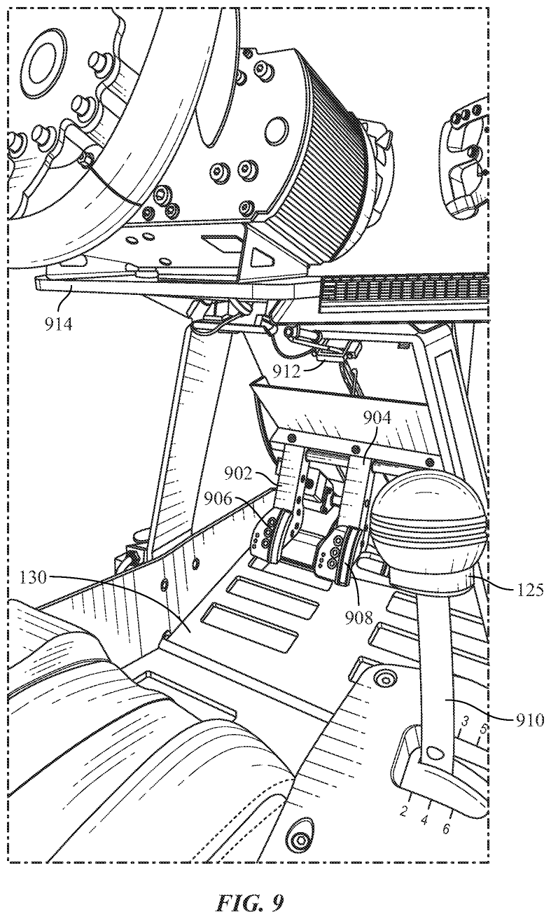

FIG. 9 illustrates a cutaway view of the virtual reality simulation chassis cockpit wherein the user sits during a driving or piloting simulation. The cockpit may include a plurality of control elements, for example foot pedals 902, 904, which are pivotally engaged to the chassis via members 906, 908 extending from each foot pedal 902, 904 to the footwell 130. In one example, the foot pedals 902, 904 provide an accelerator function and brake function during a virtual reality driving simulation. The shifter 125 is connected to a lever 910 allowing the user to manually select a gear, drive mode, speed, or other operational function related to the virtual reality simulation. A wire management system 912 retains a plurality of wires in electrical communication with the computing components provided in communication with the virtual reality simulation chassis as described hereinabove. The wire management system 912 directs the wires through apertures in top bracket 914. The top bracket may provide USB connectors or the like to be positioned in the cockpit to accept virtual reality simulator components, sensors, or to provide power to auxiliary tools utilized with the system.

In some embodiments, the joystick may be configured as a gear selector to selectively operate a maneuvering function of the simulation. For example, maneuvering function may include the selection of a gear to accelerate and decelerate the simulated vehicle. In another example, the maneuvering function may include an operation function of an aircraft in an embodiment wherein the joystick is a controller within a simulated aircraft cockpit.

In some embodiments, wires may be directed through the sidewalls, top panel, and/or bottom panel of the housing to organize wires, hide wires from view, and prevent damage thereto.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

An equivalent substitution of two or more elements can be made for any one of the elements in the claims below or that a single element can be substituted for two or more elements in a claim. Although elements can be described above as acting in certain combinations and even initially claimed as such, it is to be expressly understood that one or more elements from a claimed combination can in some cases be excised from the combination and that the claimed combination can be directed to a subcombination or variation of a subcombination.

It will be appreciated by persons skilled in the art that the present embodiment is not limited to what has been particularly shown and described hereinabove. A variety of modifications and variations are possible in light of the above teachings without departing from the following claims.

What is claimed is:

1. A virtual reality simulator apparatus, comprising:
a chassis configured to receive a cockpit, the cockpit comprised of one or more control elements to operatively control a virtual reality simulation;
a computing device to receive input from the one or more control elements and provide a plurality of output signals to a motion system engaged with the chassis, the computing device positioned within a housing having a foldable footwell, the housing configured to operate as a heat sink.

2. The simulator of claim 1, wherein the chassis is constructed as a vehicle.

3. The simulator of claim 2, wherein the vehicle is selected from the group consisting of: a motor vehicle, an aircraft, a spacecraft, a boat, a train, and a motorcycle.

4. The simulator of claim 1, wherein the computing system is in operable communication with a display to provide a visual stimulus to a user.

5. The simulator of claim 4, further comprising an audio system to provide sensory stimulus to the user.

6. The simulator of claim 1, wherein the housing is comprised of one or more fans to actively cool the housing.

7. The simulator of claim 1, wherein the computing device is mounted via vibration isolation mounts.

8. The simulator of claim 1, wherein the one or more control elements are comprised of at least one of the following: a steering wheel, one or more pedals, one or more shifters, and one or more joysticks.

9. A virtual reality simulation system, comprising:
a chassis configured to releasably engage a cockpit, the cockpit comprised of one or more control elements to operatively control a virtual reality simulation provided on a display, wherein the control elements provide a plurality of output signals to a computing device to receive the plurality of output signals from the one or more control elements and provide the plurality of output signals to a motion system engaged with the chassis, the computing device positioned within a housing to operate as a heat sink, the housing facilitating maintenance and replacement of one or more components of the computing device; and
a foldable footwell attached to a first end of the housing, the foldable footwell to receive at least one of the plurality of control elements.

10. The simulator of claim 9, wherein the cockpit is interchangeable between a plurality of vehicles and the one or more control elements.

11. The simulator of claim 10, wherein the plurality of vehicles is selected from the group consisting of: a motor vehicle, an aircraft, a spacecraft, a boat, a train, and a motorcycle.

12. The simulator of claim 11, wherein the computing system is in operable communication with a display to provide a visual stimulus to a user.

13. The simulator of claim 12, further comprising an audio system to provide sensory stimulus to the user.

14. The simulator of claim 13, wherein the housing is comprised of one or more fans to actively cool the housing.

15. The simulator of claim 14, wherein the computing device is mounted via vibration isolation mounts.

16. The simulator of claim 15, wherein the one or more control elements are comprised of at least one of the following: a steering wheel, one or more pedals, one or more shifters, and one or more joysticks.

17. The simulator of claim 16, wherein the joystick is configured to operate as a gear selector to selectively operate at least one virtual maneuvering function of the simulation.

18. The simulator of claim 17, wherein the foldable footwell is configured to releasably engage with the seat.

19. The simulator of claim 18, wherein the virtual reality simulation system operates a vehicle in a remote location.

20. A virtual reality simulation system, comprising:
a chassis configured to releasably engage a cockpit, the cockpit comprised of one or more control elements to operatively control a virtual reality simulation provided on a display, wherein the control elements provide a plurality of output signals to a computing device to receive the plurality of output signals from the one or more control elements and provide the plurality of output signals to a motion system engaged with the chassis, the computing device positioned within a housing to operate as a heat sink, the housing facilitating maintenance and replacement of one or more components of the computing device; and
a foldable footwell attached to a first end of the housing, the foldable footwell to receive at least one of the plurality of control elements and a seat.
